(19) United States
(12) Patent Application Publication
(10) Pub. No.: US 2012/0181438 A1
(43) Pub. Date: Jul. 19, 2012

(54) RADIATION DETECTING APPARATUS, RADIATION DETECTING SYSTEM, AND METHOD OF MANUFACTURING RADIATION DETECTING APPARATUS

(75) Inventors: Minoru Watanabe, Honjo-shi (JP); Chiori Mochizuki, Sagamihara-shi (JP); Keigo Yokoyama, Honjo-shi (JP); Jun Kawanabe, Kodama-gun (JP); Kentaro Fujiyoshi, Kumagaya-shi (JP); Hiroshi Wayama, Honjo-shi (JP)

(73) Assignee: CANON KABUSHIKI KAISHA, Tokyo (JP)

(21) Appl. No.: 13/328,915

(22) Filed: Dec. 16, 2011

(30) Foreign Application Priority Data
Jan. 14, 2011 (JP) 2011-005952

(51) Int. Cl. G01T 1/20; H01L 33/50

(52) U.S. Cl. 250/366; 438/65; 257/E33.061

(57) ABSTRACT

A radiation detecting apparatus includes a scintillator, a plurality of photoelectric conversion elements, and a substrate having a first surface opposing the scintillator and a second surface opposite from the first surface. The substrate, the photoelectric conversion elements and the scintillator are arranged in this order from the side of the radiation detecting apparatus where radiation enters, and the second surface includes a plurality of depressions arranged in orthogonal projection areas where orthogonal projections of the plurality of projected photoelectric conversion elements are positioned and projections parts of which are positioned in the orthogonal projection areas and the remaining areas other than the parts of which are positioned between the orthogonal projection areas.

### BACKGROUND OF THE INVENTION

1. Field of the Invention

The present invention relates to a radiation detecting apparatus and a radiation detecting system that are applied to a medical image diagnosing apparatus, a non-destructive inspection instrument, an analyzing apparatus using radiation, or the like.

2. Description of the Related Art

In recent years, thin film semiconductor manufacturing technology has been used for the manufacture of image pickup apparatuses and radiation imaging apparatuses. In particular, thin film semiconductor manufacturing technology has been used to manufacture image pickup apparatuses and radiation imaging apparatuses that include switching devices such as TFTs (thin film transistors) and conversion elements such as photoelectric conversion elements. Japanese Patent Laid-Open No. 2001-330677 proposes a radiation detector including a sensor base member having at least a plurality of photoelectric conversion elements on the side irradiated with X-rays emitted from an X-ray source and a scintillator provided on the side opposite from the side irradiated with X-rays. There is also disclosed in Japanese Patent Laid-Open No. 2001-330677 a configuration in which an entire surface of the sensor substrate or only a photoelectric converter on the sensor substrate is thinned by etching, thereby inhibiting radiation from being absorbed into the sensor substrate and improving light-receiving sensitivity and MTF (Modulation Transfer Function).

In Japanese Patent Laid-Open No. 2001-330677, the light receiving sensitivity and MTF are allegedly improved by etching only the photoelectric convertor on the sensor substrate. However, the strength of the radiation detecting apparatus is not considered at all, and hence there is room for improvement. Also, the photoelectric converter in Japanese Patent Laid-Open No. 2001-330677 is not clearly described.

### SUMMARY OF THE INVENTION

The prevent invention provides a high-resolution, high-strength radiation detecting apparatus including a substrate, a photoelectric conversion element, and a scintillator arranged in this order from the side the radiation enters.

The invention provides a radiation detecting apparatus including a scintillator configured to convert radiated radiation into visible radiation, a plurality of photoelectric conversion elements configured to convert the visible radiation converted by the scintillator into charges, and a substrate having a first surface on which the scintillator and the photoelectric conversion elements are arranged and a second surface opposite from the first surface, in which the substrate, the photoelectric conversion elements, and the scintillator are arranged in this order from the side of the radiation detecting apparatus where the radiation enter, and the second surface includes a plurality of depressions arranged in areas opposite from areas of the first surface where the photoelectric conversion elements are arranged and a plurality of projections positioned between the plurality of depressions, in which at least parts of the projections are positioned in the opposite area.

There is also provided a radiation detecting system including the radiation detecting apparatus described above, a signal processing unit configured to process signals from the radiation detecting apparatus, a recording unit configured to record the signals from the signal processing unit, a display unit configured to display the signals from the signal processing unit, and a transmission processing unit configured to transmit the signals from the signal processing unit.

The invention also provides a method of manufacturing a radiation detecting apparatus, the radiation detecting apparatus including a substrate including a first surface having a plurality of photoelectric conversion elements configured to convert visible radiation converted from radiated radiation by a scintillator into charges and a second surface opposite from the first surface, in which the substrate, the photoelectric conversion elements, and the scintillator are arranged in this order from the side of the radiation detecting apparatus where radiation enters. The method includes forming a plurality of depressions and a plurality of projections positioned between the plurality of depressions in the second surface by applying a selective thinning process to the substrate from the side of the second surface of the substrate. The plurality of depressions has been formed in areas opposite from areas of the first surface where the plurality of photoelectric conversion elements are arranged, or areas of the first surface where the plurality of photoelectric conversion elements are arranged. At least parts of the projections positioned between the plurality of depressions are formed in the opposite areas.

Accordingly, the invention provides the high-resolution, high strength radiation detecting apparatus having the substrate, the photoelectric conversion elements, and the scintillator in this order from the side where the radiation enters.

Further features of the present invention will become apparent from the following description of exemplary embodiments with reference to the attached drawings.

### BRIEF DESCRIPTION OF THE DRAWINGS

FIG. 1A is a plan view of a radiation detecting apparatus according to the invention.

FIG. 1B is a cross sectional view of the radiation detecting apparatus according to the invention.

FIG. 1C is an equivalent circuit diagram of the radiation detecting apparatus according to the invention.

FIG. 2A is an enlarged plan view of the radiation detecting apparatus according to a first embodiment of the invention.

FIG. 2B is a cross-sectional view taken along the line IIB-IIB in FIG. 2A.

FIG. 2C is a cross-sectional view taken along the line IIC-IIC in FIG. 2A.

FIG. 3A is a cross-sectional view of the radiation detecting apparatus according to another example of the first embodiment of the invention, taken along the line IIIA-IIIA in FIG. 2A.

FIG. 3B is a cross-sectional view taken along the line IIIB-IIIB in FIG. 2A.

FIGS. 4A and 4B are cross-sectional views for explaining a method of manufacturing the radiation detecting apparatus according to the first embodiment of the invention, corresponding to the line IV-IV in FIG. 2A.

FIGS. 5A and 5B are cross-sectional views for explaining another method of manufacturing the radiation detecting apparatus according to the first embodiment of the invention, corresponding to the line V-V in FIG. 2A.

FIG. 6A is an enlarged plan view of another radiation detecting apparatus according to the first embodiment of the invention.

FIG. 6B is a cross-sectional view taken along the line VIB-VIB in FIG. 6A.

FIG. 7A is an enlarged plan view of the radiation detecting apparatus according to a second embodiment of the invention.

FIG. 7B is a cross-sectional view taken along the line VIIB-VIIB in FIG. 7A.

FIG. 7C is a cross-sectional view taken along the line VIIC-VIIC in FIG. 7A.

FIG. 8A is an enlarged plan view of the radiation detecting apparatus according to a third embodiment of the invention.

FIG. 8B is a cross-sectional view taken along the line VIIIB-VIIIB in FIG. 8A.

FIG. 8C is a cross-sectional view taken along the line VIIIC-VIIIC in FIG. 8A.

FIG. 9 shows a radiation detecting system using the radiation detecting apparatus according to the invention.

### DESCRIPTION OF THE EMBODIMENTS

Referring now to the attached drawings, the embodiments of the invention will be described in detail. In this specification, the term “radiation” includes high energy particle radiation, such as α rays, β rays, and γ rays which are beams generating particles (including photons) emitted by radioactive decay, but radiation also refers to X-rays or corpuscular rays, and cosmic rays. The term “visible radiation” generally refers to radiation in the electromagnetic spectrum ranging from ultraviolet to near infrared, that is ranging from about 380 nanometers to 760 nanometers.

### First Embodiment

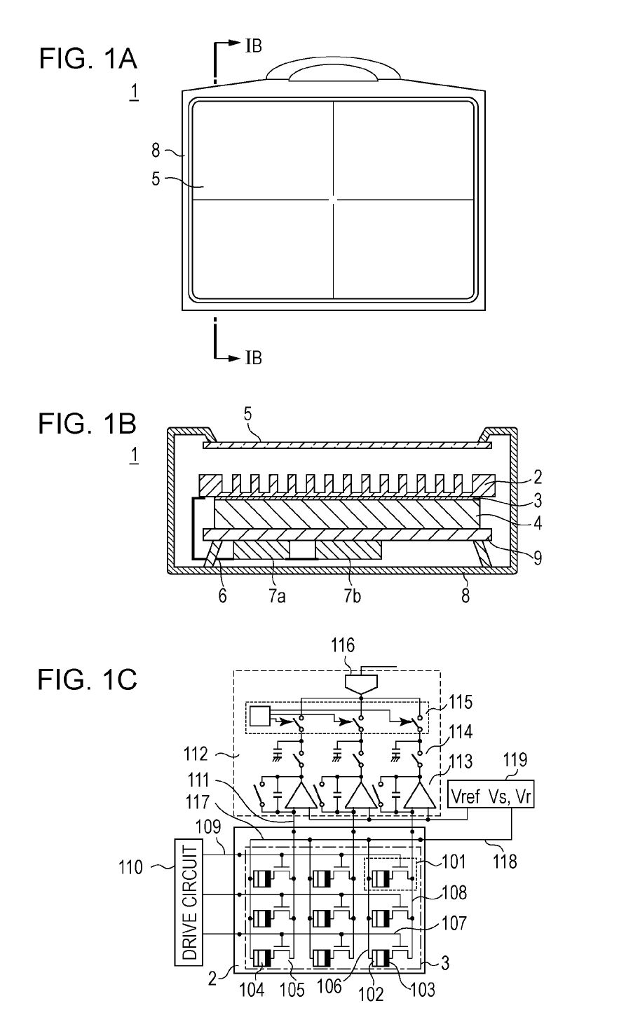

Referring now to FIGS. 1A to 1C, a radiation detecting apparatus according to a first embodiment of the invention will be described. FIG. 1A is a plan view of a radiation detecting apparatus according to the invention, FIG. 1B is a cross-sectional view taken along the line IB-IB, and FIG. 1C is an equivalent circuit diagram of the radiation detecting apparatus.

As shown in FIGS. 1A and 1B, a photoelectric converter 3 is arranged on a first surface of a substrate 2 having an insulative surface such as a glass substrate or the like. The photoelectric converter 3 includes a plurality of pixels in a two-dimensional array for converting visible radiation converted by a scintillator 4, described later, into electric signals, and the pixels each include a photoelectric conversion element and a switching device. The substrate 2 and the photoelectric converter 3 are arranged so that the radiation enters the substrate 2 from the side of a second surface opposite from the first surface. Here, for respective components in the invention, surfaces on the side where the radiation enters are referred to as “second surfaces”, and surfaces opposite from the side where the radiation enters are referred to as “first surfaces”. The second surface of the substrate 2 includes a plurality of depressions positioned in areas opposite from areas of the first surface where a plurality of photoelectric conversion elements are arranged, and a plurality of projections each positioned between adjacent ones of the plurality of depressions. The depressions and the projections will be described later in detail. Printed circuit boards 7a and 7b are mounted on an end portion of the first surface of the substrate 2 via a flexible wiring board 6. The depressions are not provided on the end portion of the substrate 2, and the end portion is desirably wider than the projection in width, and thicker than the projection. This is so that an area can be secured for mounting the printed circuit boards 7a and 7b on the substrate 2, and so that the strength for mounting the printed circuit boards 7a and 7b can be ensured.

The flexible wiring board and the printed circuit board are provided with various integrated circuits. Examples of the integrated circuit include a drive circuit 110, a reading circuit 112, a power circuit 119, and a control circuit (not shown) described later. A scintillator 4 is fixedly arranged on the surface (first surface) opposite from the surface (second surface) on the side of the photoelectric converter 3 where the radiation enters. In other words, the scintillator 4 is arranged so as to oppose the first surface of the substrate 2. The second surface of the scintillator 4 is fixedly arranged on the first surface of the photoelectric converter 3 by vapor deposition, or by adhesion. A first surface of the scintillator 4 is fixed to a second surface of the supporting base 9 installed on a housing 8 via an adhesive agent, a viscous agent, a shock absorbing material or the like. The printed circuit boards 7a and 7b are arranged on the side of a first surface of the supporting base 9. Accordingly, in the radiation detecting apparatus 1 of the invention, the substrate 2, the photoelectric converter 3, and the scintillator 4 are arranged in this order from the side of the radiation detecting apparatus 1 irradiated with the radiation.

A cover 5 is arranged on the housing 8 on the side where the radiation is incident upon (enters) the radiation detection apparatus. In this manner, an enclosure is formed by the housing 8 and the cover 5. The cover 5 allows for easy passage of radiation and has water-resistant properties and sealing properties. The substrate 2, the photoelectric converter 3, the scintillator 4, the flexible wiring board 6, and the printed circuit boards 7a and 7b are fixed to the supporting base 9 and accommodated in the enclosure formed by the housing 8 and the cover 5. The printed circuit boards 7a and 7b are arranged on the side of the second surface of the supporting base 9, so that an adverse effect of the radiation on the integrated circuit is reduced. In this manner, with the configuration in which the depressions 2a are provided on the second surface of the substrate 2 in areas corresponding the areas of the first surface where the photoelectric conversion elements are arranged, the thickness of the substrate 2 in the area where the photoelectric conversion elements are arranged is reduced in comparison with the substrate where the depressions 2a are not provided, whereby the amount of radiation passing through the substrate 2 is increased. Also, since the radiation passing through the substrate 2 is increased in comparison with the substrate having no depressions 2a, the amount of light emission of the scintillator 4 is increased and the amount of visible radiation irradiated on the photoelectric converter 3 is increased correspondingly, which leads to an improvement in the sensitivity. In addition, since the distance between the position at which light is emitted from the scintillator 4 and the photoelectric converter 3 is short, scattering of visible radiation is inhibited and MTF (sharpness) is improved.

Examples of the substrate 2 include a glass substrate, a silicon substrate, and a hard carbon substrate having heat-resistant properties with respect to the process temperature for the formation of the photoelectric converter 3. Substrates manufactured by forming an organic or inorganic insulation film on the surface of the substrate material may be used as the substrate 2. Examples of the insulating film which may be used include inorganic insulating films such as a silicon oxide film or a silicon nitride film, or organic insulating films such as PET (polyethylene terephthalate) or PI (polyimide). It is also possible to form depressions and projections on the second surface of the substrate 2 after the formation of the photoelectric converter 3 so as to achieve a suitable thickness by thinning the surface of the substrate material on the side where the radiation enters partly by etching or CMP. Also, a substrate having a predetermined thickness having been formed with depressions and projections in advance by molding may be prepared. In this manner, by using the substrate 2 having partly thinned areas, the amount of radiation passing through the substrate 2 is increased. Here, when applying a thinning process on the substrate material after the scintillator 4 has been fixedly arranged on the first surface of the photoelectric converter 3, a protective material may be arranged on the side of the front surface of the scintillator 4. It is because the shape may be deformed when vibrations are applied on a phosphor layer in a case where particle phosphor such as GD₂O₂S:Tb is used in the phosphor layer used in the scintillator 4. The same applies to a case where an alkali column crystalline structure such as CsI:Tl or CsI:Na is used in the phosphor layer. Therefore, it is desirable to arrange some sort of protective material on a first surface of the scintillator 4 arranged on the side opposite from the second surface of the substrate 2. A thinning process may further be performed on the protective material. The protective material may be the same material as the substrate 2 or, alternatively, the protective material may be used as part of the supporting base 9.

Referring now to FIG. 1C, a schematic equivalent circuit of the radiation detecting apparatus according to the first embodiment of the invention will be described. Although a three-rows three-column equivalent circuit diagram has been used for the sake of simplification of the description in FIG. 1C, the invention is not limited thereto, and the radiation detecting apparatus includes a pixel array of n-rows by m-columns (both of n and m are natural numbers not smaller than 2). The radiation detecting apparatus according to the first embodiment includes the photoelectric converter 3 having a plurality of pixels 101 arranged in the row direction and the column direction provided on the first surface of the substrate 2. Each pixel 101 includes a photoelectric conversion element 104 configured to convert radiation or light into charge and a switching device 105 configured to output electric signals in accordance with the charge of the photoelectric conversion element 104. In the first embodiment, a metal insulator semiconductor (MIS) photoelectric conversion element is used as the photoelectric conversion element, and a thin film transistor (TFT) is used as a switching element. The photoelectric conversion element 104 includes a first electrode 103, a second electrode 102, and a semiconductor layer arranged therebetween. Here, the first electrode 103 is formed of a third conductive layer 207, the second electrode 102 is formed of a fourth conductive layer 211, and a semiconductor layer is formed of a second semiconductor layer 209. The scintillator 4 configured to convert the wavelength of the radiation into that of visible radiation which can be detected by the photoelectric conversion element 104 is arranged on the surface on the side of the second electrode of the photoelectric conversion element 104 (a first surface of the photoelectric converter 3). First main electrodes of the switching devices 105 are electrically connected to the first electrodes 103 of the photoelectric conversion elements 104, and the bias lines 106 are electrically connected to the second electrodes 102 of the photoelectric conversion elements 104. Each of the bias lines 106 is connected commonly to the second electrodes 102 of the photoelectric conversion elements 104 arranged in the column direction. Drive lines 107 are electrically connected to control electrodes of the switching devices 105, and signal lines 108 are electrically connected to second main electrodes of the switching devices 105. Each of the drive lines 107 is commonly connected to the control electrodes of the plurality of switching devices 105 arranged in the row direction, and the drive lines 107 are electrically connected to a drive circuit 110 via first connecting wiring 109. The drive circuit 110 supplies drive pulses to the plurality of drive lines 107 arranged in the column direction in sequence or simultaneously, whereby electric signals from pixels to the plurality of signal lines 108 arranged in the row direction are output in parallel on a row-to-row basis. Each of the signal lines 108 is commonly connected to the second main electrodes of the plurality of switching devices 105 arranged in the column direction, and the signal lines 108 are electrically connected to a reading circuit 112 via second connecting wiring 111. The reading circuit 112 includes, on a signal line to signal line basis, integrating amplifiers 113 configured to integrate and amplify the electric signals from the signal lines 108 and sample and hold circuits 114 configured to sample and hold the electric signals amplified by and output from the integrating amplifiers 113. The reading circuit 112 further includes a multiplexer 115 configured to convert electric signals output from the plurality of sample and hold circuits 114 in parallel into electric signals in series and an analogue-to-digital converter 116 configured to convert outputs of electric signals into digital data. A reference potential Vref is supplied from the power circuit 119 to noninverting input terminals of the reading circuit 112. The power circuit 119 is also electrically connected to the plurality of bias lines 106 arranged in the row direction via a common bias line 117 and a third connecting wiring 118, and supplies a bias potential Vs or an initialization potential Vr to the second electrodes 102 of the photoelectric conversion elements 104.

An operation of the radiation detecting apparatus according to the first embodiment will be described below. The reference potential Vref is applied to the first electrodes 103 of the photoelectric conversion elements 104 via switching devices 105, and the bias potential Vs is applied to the second electrodes 102, whereby a bias which depletes the photoelectric conversion layer of the MIS photoelectric conversion element is applied to the photoelectric conversion elements 104. In this state, a subject is irradiated with radiation in test. The radiation passes through the subject while being attenuated therein, and is converted into visible radiation by the scintillator 4. This visible radiation enters the photoelectric conversion elements 104 and is converted into charges. Electric signals corresponding to the charges are output to the signal lines 108 when the switching devices 105 are brought into a conductive state by drive pulses applied from the drive circuit 110 to the drive lines 107 and are read to the outside by the reading circuit 112 as digital data. Subsequently, the switching devices 105 are brought into a conductive state by changing the potential of the bias lines 106 from the bias potential Vs to the initialization potential Vr, so that positive or negative carriers generated in the photoelectric conversion elements 104 and remaining therein are eliminated. Subsequently, the potential of the bias lines 106 is changed from the initialization potential Vr to the bias potential Vs, so that initialization of the photoelectric conversion elements 104 is achieved.

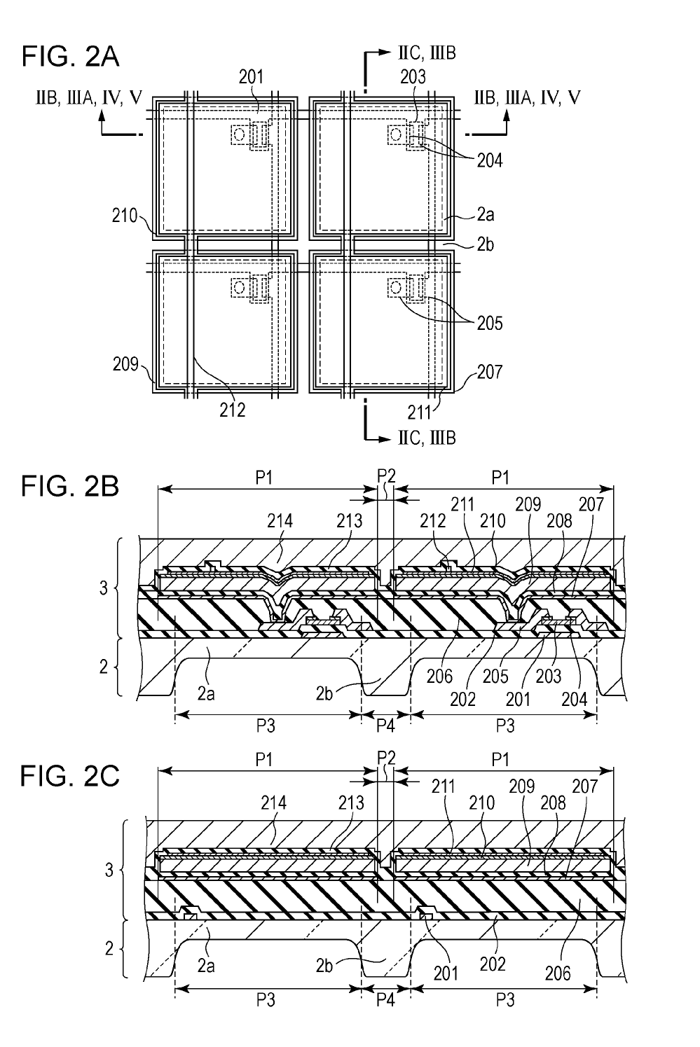

Referring now to FIGS. 2A to 2C, the relationship between the pixels and the depressions and projections of the substrate 2 will be described. FIG. 2A, which is a plan view, shows a partial area of the substrate 2 and the photoelectric converter 3 in FIGS. 1B and 1C in an enlarged scale, in which an insulative member is not described for simplicity. FIG. 2B is a cross-sectional view taken along the line IIB-IIB in FIG. 2A, and FIG. 2C is a cross-sectional view taken along the line IIC-IIC in FIG. 2A.

First conductive layers 201, a first insulating layer 202, first semiconductor layers 203, first impurity semiconductor layers 204, and second conductive layers 205 are arranged in sequence on the first surface of the substrate 2. Here, the first conductive layers 201 constitute control electrodes of the switching devices 105 and the drive lines 107, the first insulating layer 202 constitute gate insulating films of the switching devices 105, and the first semiconductor layers 203 constitute channels of the switching devices 105. The first impurity semiconductor layers 204 become ohmic contacts of the switching devices 105, and the second conductive layers 205 become two main electrodes and the signal lines 108 of the switching devices 105. Second insulating layers 206 are arranged between the switching devices 105 and the photoelectric conversion elements 104. The second insulating layers 206 function as insulating interlayers. Third conductive layers 207 which become the first electrodes 103 of the photoelectric conversion elements 104 are electrically coupled to the second conductive layers 205 which become the first main electrodes of the switching devices 105 via through holes provided in the second insulating layers 206. The third conductive layers 207, third insulating layers 208, second semiconductor layers 209, second impurity semiconductor layers 210, fourth conductive layers 211, and fifth conductive layers 212 are arranged in sequence on the second insulating layers 206 on the opposite side from the substrate 2. Here, the third insulating layers 208 become complete insulating layers, the second semiconductor layers 209 become photoelectric conversion layers, the second impurity semiconductor layers 210 become hole blocking layers, the fourth conductive layers 211 become the second electrodes 102 of the photoelectric conversion elements 104, and the fifth conductive layers 212 become the bias lines 106. Although the third insulating layers 208 are employed in this embodiment because the MIS photoelectric conversion elements 104 are employed, the invention is not limited thereto. When PIN photodiodes are employed as the photoelectric conversion elements 104, third impurity semiconductor layers which function as electron blocking layers may be employed instead of the third insulating layers 208. In this case, the hole blocking layers and the electron blocking layers may be interchanged. The plurality of photoelectric conversion elements 104 are covered with fourth insulating layers 213 which serve as passivation films, and the scintillator 4 (not shown) is provided above fifth insulating layers 214 which function as planarizing layers provided on the fourth insulating layers 213. Here, the width P1 of the photoelectric conversion element 104 in the invention is defined by the width of the third conductive layer 207 which becomes the first electrode 103 of the photoelectric conversion element 104. The width P2 between adjacent ones of the photoelectric conversion elements 104 is defined by the width between the third conductive layers 207.

The substrate 2 is partly removed from the second surface side thereof, and hence has the plurality of depressions 2a and projections 2b. The depressions 2a are positioned in areas of the second surface of the substrate 2 which are opposite the areas of the first surface of the substrate 2 where the photoelectric conversion elements 104 are arranged and have a width indicated by P3. In other words, the depressions 2a are positioned in areas on the second surface of the substrate 2 where the plurality of photoelectric conversion elements 104 is orthogonally projected from the side of the scintillator 4 in the direction vertical to the substrate 2 (the orthogonal projection areas of the photoelectric conversion elements 104). In the invention, the orthogonal projection areas of the photoelectric conversion elements 104 mean areas on the second surface of the substrate 2 where the orthogonal projections of the first electrodes 103 of the photoelectric conversion elements 104 are positioned. The projections 2b are each positioned between adjacent ones of the plurality of depressions 2a on the second surface of the substrate 2, and the width is indicated by P4. Here, the depressions 2a in the invention are areas having a thickness of 50% or smaller of the thickness of the thickest portions of the projections 2b, and the width P3 of the depressions 2a is defined by the width of the areas having a thickness of 50% or smaller. The projections 2b are areas having a thickness of 50% or larger of the thickest portions of the projections 2b, and the width P4 is defined by the width between the adjacent projections 2b. In this manner, owing to the positioning of the depressions 2a in the areas on the second surface of the substrate 2 which are opposite the areas of the first surface of the substrate 2 where the photoelectric conversion elements 104 are arranged, the amount of radiation passing through the substrate 2 is increased, and hence the radiation detecting apparatus with a higher sensitivity is provided.

In the invention, parts of the projections 2b are positioned within the areas on the second surface of the substrate 2 opposite from the areas where the photoelectric conversion elements 104 are arranged, and the remaining portions of the projections 2b other than the parts described above are positioned between the areas on the second surface of the substrate 2 opposite from the areas where the photoelectric conversion elements 104 are arranged. In other words, parts of the projections 2b are each positioned on the second surface of the substrate 2 within the area of each of the orthogonal projection areas of the photoelectric conversion elements 104, and the remaining portions other than the parts are each positioned on the second surface between adjacent ones of the areas of the orthogonal projection areas of the photoelectric conversion elements 104. In this embodiment, the projections 2b each lie on the second surface of the substrate 2 astride the area opposite a portion positioned between adjacent one of the photoelectric conversion elements 104 and the area where each of the photoelectric conversion elements 104 is arranged. In other words, the width P3 of the depressions 2a is smaller than the width P1 of the photoelectric conversion elements 104, and the width P4 of the projections 2b is larger than the width P2 between the photoelectric conversion elements 104. In this embodiment, the projections 2b are arranged in a reticular pattern, which further improves the mechanical strength of the substrate 2. In this structure, even when the depressions are provided on the second surface of the substrate 2 corresponding to the photoelectric conversion elements 104 for increasing the amount of passage of the radiation, the strength of the substrate 2 is secured in a wider area. The substrate strength is particularly secured when, as shown in FIG. 2B, the photoelectric converter 3 has a structure in which the switching devices 105 are arranged between the photoelectric conversion elements 104 and the substrate 2 so as to be covered with the photoelectric conversion element 104. In this stacked structure, the areas where the photoelectric conversion elements 104 are arranged occupy approximately 90% of the first surface of the substrate 2. In such a case, the projections 2b of the substrate 2 occupy only 10% or less of the entire photoelectric converter 3, and hence it is difficult to secure the strength of the substrate 2. Although it depends on the application, a pixel pitch (P1+P2) used in a radiation detecting apparatus is 70 to 200 μm. For example, when a glass substrate having a thickness of 0.5 to 0.7 mm is used as the substrate 2, it is necessary to include the projections 2b not less than 20% of the entire substrate 2. Therefore, the value P3 is preferably smaller than 63 to 180 μm and the value P4 is preferably not smaller than 7 to 20 μm. Examples of the shape of the projections 2b here include R-chamfered, C-chamfered, and tapered shapes. When a glass substrate having a thickness of 0.2 to 0.3 mm is used as the substrate 2, it is necessary to include the projections 2b not less than 40% of the entire substrate 2. Therefore, the value P3 is preferably smaller than 45 to 150 μm and the value P4 is preferably not smaller than 15 to 45 μm. In this configuration, even with the stacked structure in which the photoelectric conversion elements 104 are arranged above the switching devices 105, the amount of the passage of the radiation from the second surface can be increased while maintaining the mechanical strength of the substrate 2.

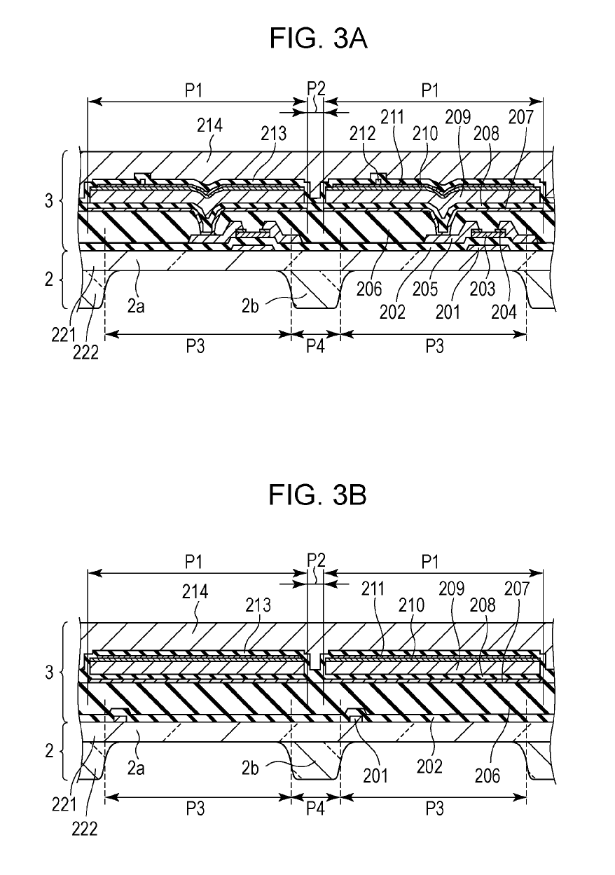

The material of the substrate 2 is not necessarily formed of one kind of substrate material. For example, as shown in FIGS. 3A and 3B, a plurality of (two) substrate materials may be used. FIG. 3A is a cross-sectional view taken along the line IIIA-IIIA in FIG. 2A, and FIG. 3B is a cross-sectional view taken along the line IIIB-IIIB in FIG. 2A. In FIGS. 3A and 3B, a first substrate 221 on the side of the first surface of the substrate 2 is suitably formed of a material which allows easy passage of the radiation, for example, a resin film or a carbon film, and a second substrate 222 on the side of the second surface of the substrate 2 is suitably formed of a material providing high machining accuracy and having high rigidity, for example, a glass substrate. The materials used for the substrate 2, the first substrate 221, and the second substrate 222 suitably have a heat-resistance which resists heat required in a semiconductor process and a scintillator forming process. The material used for the second substrate 222 is suitably a substrate material containing a material having a lower transmissivity with respect to the radiation in comparison with the first substrate 221 which constitute the depressions 2a, such as lead (Pb). With the configuration of the projections 2b including the second substrate 222, an effect of elimination of the scattered radiation is added, and hence the radiation detecting apparatus with high sensitivity, high strength, and higher sharpness is provided.

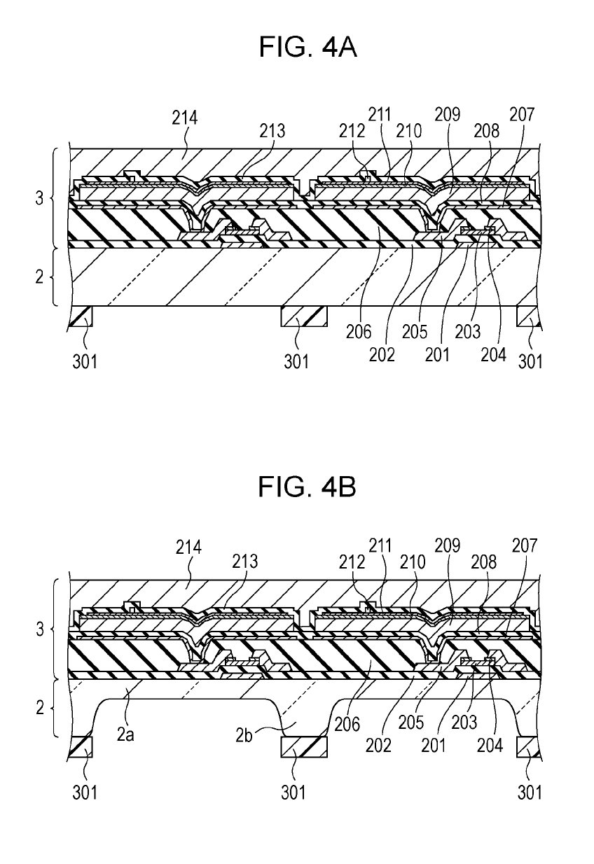

Referring now to FIGS. 4A and 4B, a method of manufacturing the radiation detecting apparatus according to the invention will be described. Since known technologies are used in a process of manufacturing the scintillator 4 and the photoelectric converter 3, detailed descriptions thereof will be omitted. FIGS. 4A and 4B are cross-sectional views corresponding to IV-IV in FIG. 2A.

As shown in FIG. 4A, first of all, in a state in which the photoelectric converter 3 and the scintillator 4 (not shown) are arranged on the first surface of the substrate 2, resists 301 are formed on desired areas on the second surface of the substrate 2. The resist 301 is patterned by photolithography, and is patterned into a desired pattern with respect to the formed photoelectric converter 3. Here, the desired areas and the desired pattern are areas and a pattern corresponding to the areas where the projections 2b are formed.

Subsequently, as shown in FIG. 4B, a plurality of depressions and projections are formed on the second surface of the substrate 2 by performing a selective thinning process from the second surface side of the substrate 2 using the resists 301. Although there are several methods for thinning, dry etching having a higher anisotropy is suitably employed for achieving a higher aspect ratio of the projections. If the aspect ratio is small due to the thickness of the substrate 2 or the pitch of the photoelectric conversion elements, thinning may be achieved by wet etching. If the substrate 2 is formed of a film mainly formed of resin or carbon, the thinning process may be achieved by an oxygen plasma process. Subsequently, by removing the resists 301, the radiation detecting apparatus shown in FIGS. 2A to 2C is obtained.

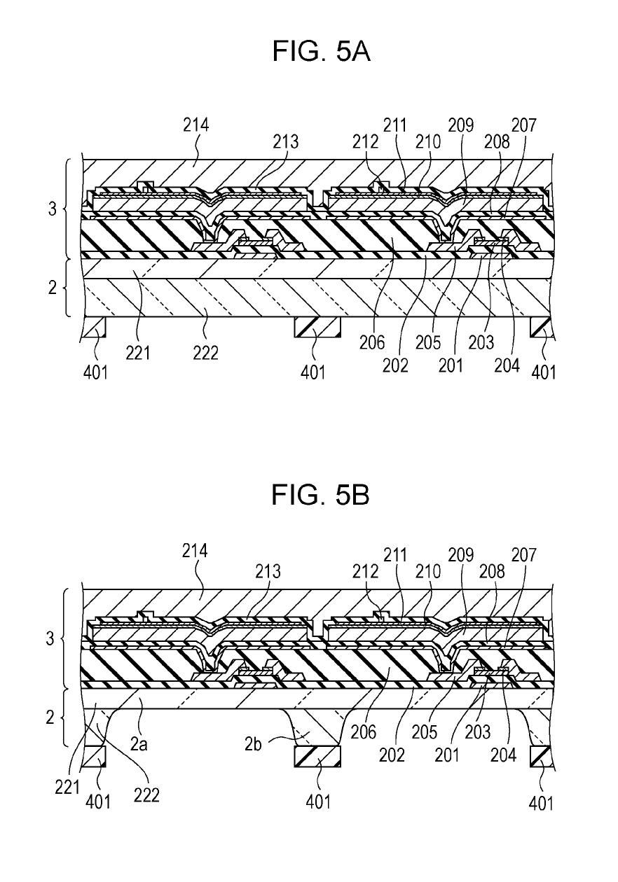

A case where the first substrate 221 and the second substrate 222 shown in FIGS. 3A and 3B are used will also be described. As shown in FIG. 5A, first of all, in a state in which the photoelectric converter 3 and the scintillator 4 (not shown) are arranged on the first substrate 221 on the side of the first surface of the substrate 2 including a first substrate 221 and the second substrate 222, resists 401 are formed on desired areas on the second surface of the substrate 2. The resist 401 is patterned by photolithography, and is patterned into a desired pattern with respect to the formed photoelectric converter 3. Subsequently, as shown in FIG. 5B, a plurality of depressions and projections are formed on the second surface of the substrate 2 by performing a selective thinning process from the second surface side of the substrate 2 using the resists 401. If the selective thinning process is desired to be performed on the second substrate 222, a selective ratio in which the etching property with respect to the second substrate 222 is high, and the etching property with respect to the first substrate 221 is low is suitably selected. For example, the second substrate 222 may be a thick film mainly formed of carbon, the first substrate 221 is a SiN film or SiO₂ film, and oxygen plasma is used for thinning.

In the first embodiment, the process in which the substrate 2 having the photoelectric converter 3 and the scintillator 4 arranged thereon is thinned is described. However, the invention is not limited thereto. The scintillator 4 may be formed after the thinning process of the substrate 2, and the photoelectric converter 3 may also be formed after the thinning of the substrate 2. However, a state in which the photoelectric converter 3 is arranged on the first surface of the substrate 2 is more suitable because the alignment with respect to the photoelectric converter 3 is easier.

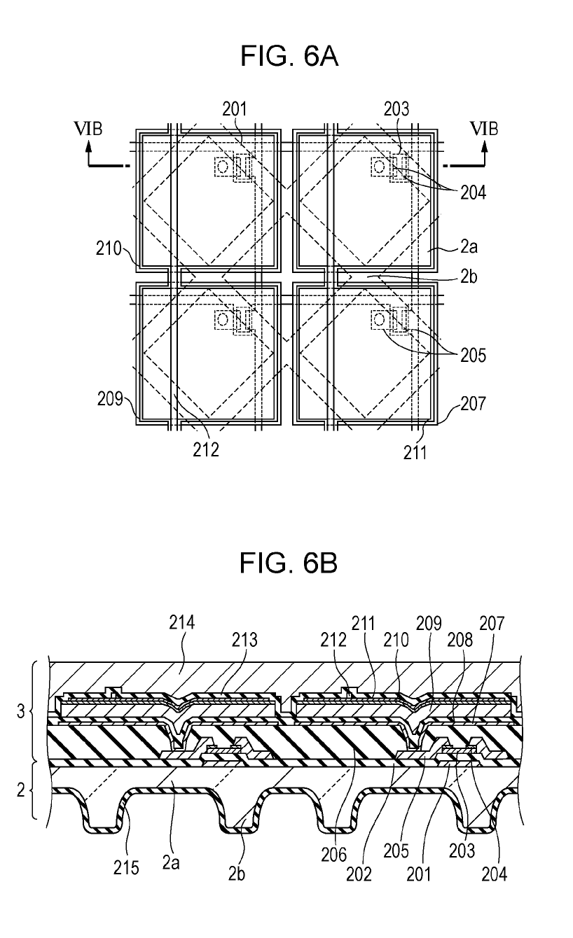

In this embodiment, the shape of the depressions 2a have been described to have a rectangular shape including two sides parallel to the drive lines 107 and two sides parallel to the signal lines 108, that is, a rectangular shape including four sides parallel to the sides of the first electrode 103 of the photoelectric conversion element 104. However, the invention is not limited thereto. For example, the depressions may have a polygonal shape (for example, a rectangular shape) having a side which is not parallel to the drive lines 107 and the signal lines 108, that is, having at least one side which is not parallel to side of the first electrode 103 of the photoelectric conversion element 104 as shown in FIGS. 6A and 6B. The polygonal shape may be the shape other than the rectangular shape, and may be a triangle, a combination of a pentagon and a hexagon, or an octagon suitably used. The depressions 2a may have a circular shape. By employing the polygon or the circle as the shape of the depressions 2a, the projections 2b are arranged in a reticular pattern, which further improves the mechanical strength of the substrate 2. With the configuration of the substrate 2 as described above, the mechanical strength which resists the stresses of the drive lines 107 and the signal lines 108 is increased, and the mechanical strength of the substrate 2 is further increased, whereby the radiation detecting apparatus with high strength is provided.

If the photoelectric converter 3 has the stacked structure in which the switching devices 105 are arranged between the photoelectric conversion elements 104 and the substrate 2 so as to be covered with the photoelectric conversion element 104, at least parts of the projections 2b are suitably positioned on the second surface of the substrate 2 within the orthogonal projection areas of the switching devices 105. Accordingly, the mechanical strength of the substrate 2 is further increased, and the radiation detecting apparatus with higher strength is provided. Also, the depressions 2a are suitably arranged so that the projections 2b are positioned in the areas on the second surface opposite from the first surface of the substrate 2 where the drive lines 107 and the signal lines 108 are arranged.

It is more suitable to provide a light absorbing layer 215 formed of a material having a high absorbancy with respect to the visible radiation converted by the scintillator 4 for absorbing the visible radiation on the second surface of the formed substrate 2. Accordingly, the light reflected in a scattered manner by the second surface having the depressions and projections of the substrate 2 is reduced, and hence the radiation detecting apparatus with higher sharpness is provided. The light absorbing layer 215 may be applied adequately to the configuration shown in FIGS. 2A to 2C and a configuration of an embodiment described later.

### Second Embodiment

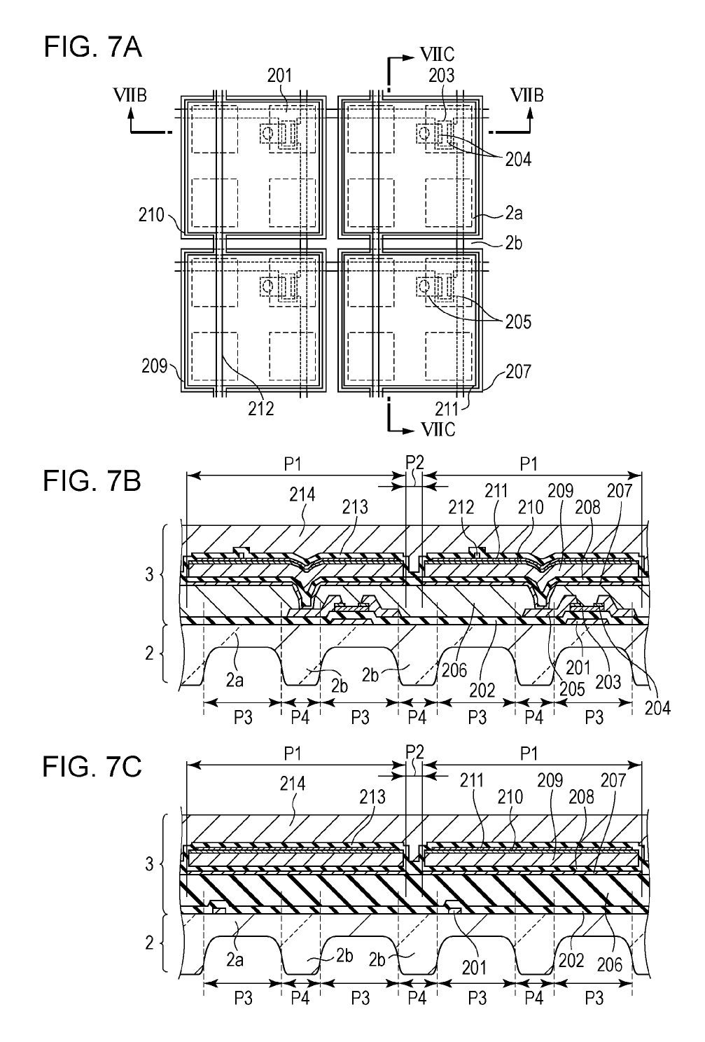

Referring now to FIGS. 7A to 7C, a second embodiment of the invention will be described. The same components as those described in the first embodiment are denoted by the same numbers, and detailed description will be omitted.

One depression 2a is provided correspondingly to one photoelectric conversion element 104 in the first embodiment. However, in the second embodiment, a plurality of (two, for example) depressions 2a are provided for one photoelectric conversion element 104. In other words, assuming that k is a natural number of two or larger, the pitch P3 of the depressions 2a is smaller than 1/k times the pitch P1 of the photoelectric conversion elements 104. With this configuration, the projections 2b are positioned such that the entire widths thereof are arranged in areas of the second surface of the substrate 2 which are opposite the areas of the first surface of the substrate 2 where the photoelectric conversion elements 104 are arranged. Accordingly, the mechanical strength of the substrate 2 is further increased, and the radiation detecting apparatus with higher strength is provided. Also, accordingly, a pseudo low-pass filter is inserted spatially, and hence the radiation detecting apparatus with higher sharpness with reduced moiré fringes is provided. Since the first embodiment corresponds to a case where k=1, the pitch P3 of the depressions 2a is desirably smaller the 1/k times the pitch P1 of the photoelectric conversion elements, where k is a natural number of 1 or larger in the invention. The configuration in the second embodiment may also be applied adequately to a polygon (for example, rectangle) having a plurality of sides which are not parallel to the drive lines 107 and the signal lines 108 as shown in FIGS. 6A and 6B.

### Third Embodiment

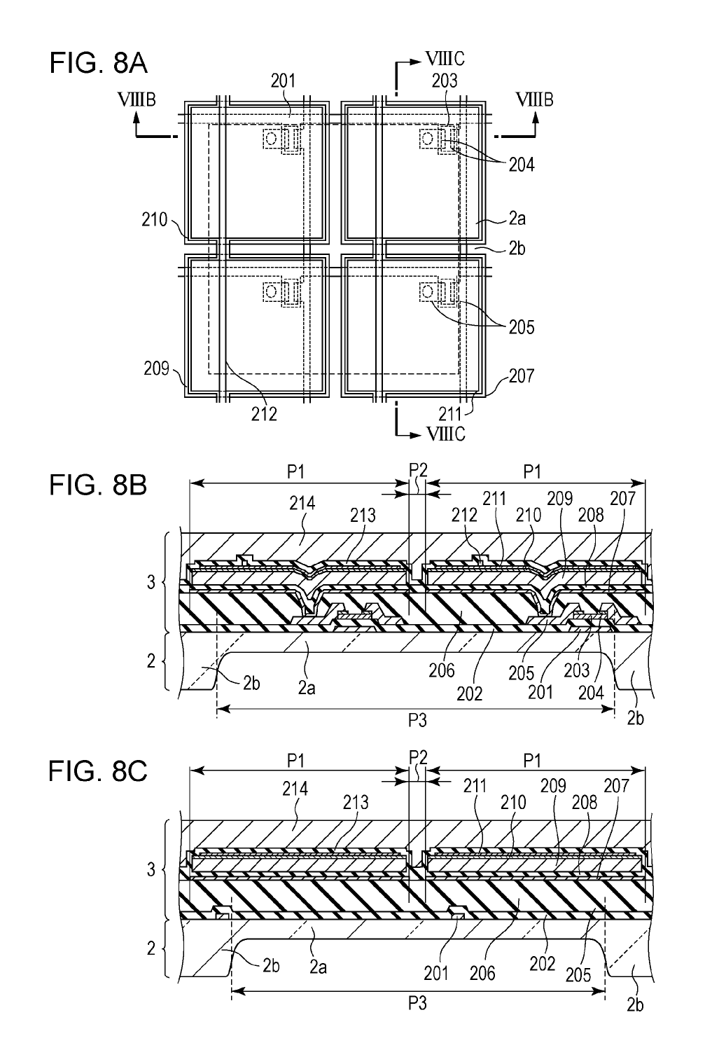

Referring now to FIGS. 8A to 8C, a third embodiment of the invention will be described. The same components as those described in the first or second embodiment are denoted by the same numbers, and detailed description will be omitted.

One or more depressions 2a are provided correspondingly to one photoelectric conversion element 104 in the first and second embodiments. However, in the third embodiment, one depression 2a is provided astride a plurality of photoelectric conversion elements 104 (four in two rows and two columns, for example). In other words, assuming that k is a natural number of one or larger, the pitch P3 of the depressions 2a is not smaller than k times the pitch P1 of the photoelectric conversion elements 104. However, in such a case, in order to secure the mechanical strength of the substrate 2, the depressions 2a are suitably arranged so that the projections 2b are positioned in the areas on the second surface opposite from the areas on the first surface of the substrate 2 where the drive lines 107 and the signal lines 108 are arranged. Accordingly, assuming that k is a natural number of one or larger, required mechanical strength of the substrate 2 is secured even in a case where the pitch P3 of the depressions 2a is not smaller than k times the pitch P1 of the photoelectric conversion elements 104. Although an example has been described in the third embodiment in which one depression 2a is positioned in an area corresponding to the areas where four photoelectric conversion elements 104 are arranged on the first surface of the substrate 2, the invention is not limited thereto. Assuming that k is a natural number of two or larger, one depression 2a may be positioned in an area corresponding to the areas where the k photoelectric conversion elements 104 are arranged on the first surface of the substrate 2. However, it is desirable that the arrangement and the shape of the depressions 2a are determined so that the areas where the plurality of photoelectric conversion elements 104 are arranged equal to the overlapped area of the depression 2a. It is for equalizing the amount of radiation which passes each pixel.

The configuration in the third embodiment may also be applied adequately to a polygon (for example, a rectangle) having a plurality of sides which are not parallel to the drive lines 107 and the signal lines 108 as shown in FIGS. 5A and 5B. It is also possible to provide one depression 2a for the plurality of photoelectric conversion elements arranged in one row or in one column. In this case, the plurality of depressions 2a or the plurality of projections 2b are arranged in stripes. In such a case, the depressions 2a are suitably arranged so that the projections 2b are positioned in the areas on the second surface opposite from the areas on the first surface of the substrate 2 where the drive lines 107 or the signal lines 108 are arranged. It is also possible to provide one depression 2a with respect to a plurality of photoelectric conversion elements 104 arranged in a direction not parallel to the direction of the row or the direction of the column (arranged obliquely). In this case, the plurality of depressions 2a or the plurality of projections 2b are arranged in oblique stripes. In such a shape, when wet etching or the like is used for forming the depressions 2a and the projections 2b, etching liquid circulates well and the entire part is uniformly thinned. Therefore, image artifacts due to the irregular transmission of the radiation is prevented, and hence the radiation detecting apparatus with higher sharpness is provided.

### Fourth Embodiment

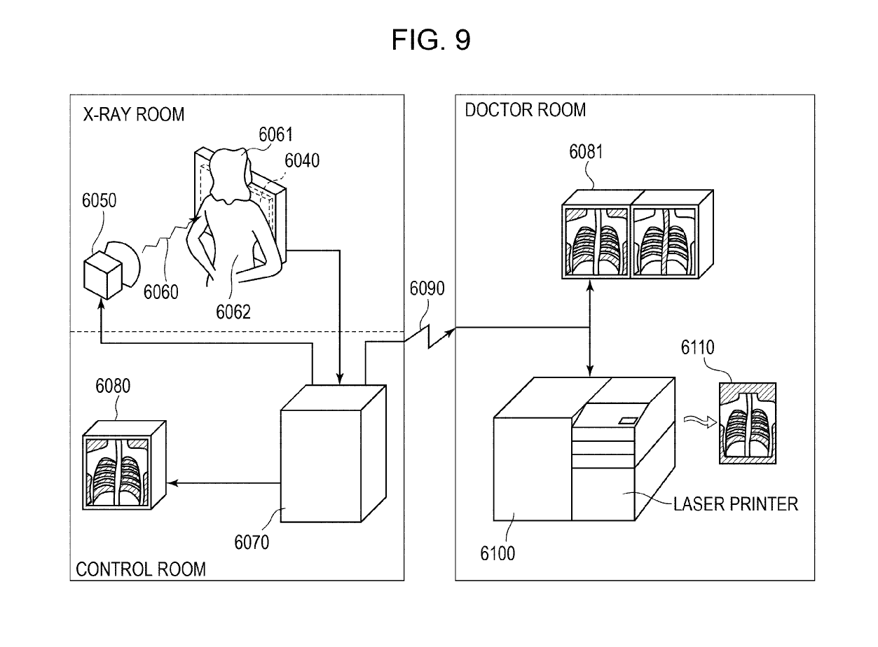

Referring now to FIG. 9, a radiation detecting system using the radiation detecting apparatus according to the invention will be described.

An X-ray 6060 generated in an X-ray tube 6050 passes through a chest portion 6062 of a patient or a test subject 6061, and enters a radiation detecting apparatus 6040 having the scintillator 4 arranged on the first surface of the photoelectric converter 3. The entered X-ray includes information on the test subject 6061 within the body. The scintillator 4 emits light corresponding to the entry of the X-ray, and the electrical information is obtained by converting the emitted light by the photoelectric converter 3. This information is converted into digital data, and is subjected to image processing by an image processor 6070 as a signal processing unit, thereby being displayed on a display 6080 as a display unit of the control chamber.

This information can be transmitted to distant places by a transmission processing unit such as a telephone circuit 6090, and can be displayed on the display 6081 as a display unit in a different place such as a doctor room or stored in a recording unit such as an optical disk, whereby doctors at the distant places are capable of diagnosing. It is also possible to record the information in a film 6110 which is recording medium by the film processor 6100 as a recording unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-005952 filed Jan. 14, 2011, which is hereby incorporated by reference herein in its entirety.

What is claimed is:

1. A radiation detecting apparatus comprising:
a scintillator configured to convert radiation incident on a side of the radiation detection apparatus into visible radiation;
a plurality of photoelectric conversion elements configured to convert the visible radiation into electric charges; and
a substrate having first and second surfaces, the first surface facing the scintillator and the second surface being opposite to the first surface;
wherein the substrate, the photoelectric conversion elements, and the scintillator are arranged in order from the side of the radiation detecting apparatus where the radiation is incident thereupon, and
wherein the second surface includes a plurality of depressions arranged in orthogonal projection areas where orthogonal projections of the plurality of photoelectric conversion elements projecting from the side of the scintillator in a direction perpendicular to the substrate and projections parts of which are positioned in the orthogonal projection areas and remaining parts of which are positioned between the orthogonal projection areas.

2. The radiation detecting apparatus according to claim 1, further comprising a switching device arranged between the photoelectric conversion elements and the first surface of the substrate,
wherein the photoelectric conversion elements are arranged between the first surface of the substrate and the scintillator.

3. The radiation detecting apparatus according to claim 2, wherein
the switching device is arranged so as to be covered with the photoelectric conversion elements.

4. The radiation detecting apparatus according to claim 3,
wherein each of the photoelectric conversion elements includes an electrode which is electrically coupled with the switching device,
wherein the shape of the depressions is a circle or a polygon having at least one side which is not parallel to the side of the electrode, and
wherein the projections are arranged in a reticular pattern.

5. The radiation detecting apparatus according to claim 1,
wherein the substrate is formed of a plurality of substrate materials, and
wherein a substrate material contained in the projections from among the plurality of substrate materials has lower transmissivity with respect to radiation in comparison with a substrate material which constitutes the depressions.

6. The radiation detecting apparatus according to claim 1, further comprising:
a light absorbing layer arranged on the second surface and configured to absorb visible radiation converted by the scintillator.

7. The radiation detecting apparatus according to claim 1, wherein
the width of the depressions is smaller than the width of the photoelectric conversion elements.

8. The radiation detecting apparatus according to claim 1, wherein
the depressions are provided so that one of the depressions is provided across a plurality of photoelectric conversion elements.

9. A radiation detecting system comprising:
the radiation detecting apparatus according to claim 1,
a signal processing unit configured to process a signal from the radiation detecting apparatus;
a recording unit configured to record the signal from the signal processing unit;
a display unit configured to display the signal from the signal processing unit, and
a transmission processing unit configured to transmit the signals from the signal processing unit.

10. A method of manufacturing a radiation detecting apparatus, the radiation detecting apparatus including a scintillator configured to convert radiated radiation into visible radiation; a plurality of photoelectric conversion elements configured to convert the visible radiation converted by the scintillator into charges; and a substrate having a first surface opposing the scintillator and a second surface opposite from the first surface, and being configured in such a manner that the substrate, the photoelectric conversion elements, and the scintillator are arranged in order of the substrate, the photoelectric conversion elements, and the scintillator from the side of the radiation detecting apparatus where radiation enters, the method comprising:
forming a plurality of depressions and a plurality of projections, each of the projections being positioned between adjacent ones of the plurality of depressions on the second surface,
wherein the plurality of depressions are formed in orthogonal projection areas where orthogonal projections of a plurality of photoelectric conversion elements projecting from the side of the scintillator in the direction perpendicular to the substrate are positioned, and
wherein parts of the projections are formed within the orthogonal projection areas and remaining portions other than the parts of the projections are formed between the orthogonal projection areas.

11. The method of manufacturing a radiation detecting apparatus according to claim 10, wherein
the substrate is subjected to a selective thinning process from the side of the second surface of the substrate.

12. The method of manufacturing a radiation detecting apparatus according to claim 11, wherein
the substrate is subjected to the selective thinning process in a state in which the plurality of photoelectric conversion elements have been arranged on the first surface.
